(19) United States
(12) Patent Application Publication
(10) Pub. No.: US 2026/0302032 A1
(43) Pub. Date: Oct. 1, 2026

(54) MAGNETORESISTANCE EFFECT ELEMENT

(71) Applicant: TDK Corporation, Tokyo (JP)

(72) Inventors: Do BANG, Tokyo (JP); Kazuumi INUBUSHI, Tokyo (JP); Tomoyuki SASAKI, Tokyo (JP)

(73) Assignee: TDK Corporation, Tokyo (JP)

(21) Appl. No.: 19/091,872

(22) Filed: Mar. 27, 2025

(51) Int. Cl. H01F 10/32; G01R 33/09; G11B 5/39; H03H 7/06; H10B 61/00

(52) U.S. Cl. CPC H01F 10/32; G01R 33/09; G11B 5/39; H03H 7/06; H10B 61/10

(57) ABSTRACT

A magnetoresistance effect element includes: a laminate including a first ferromagnetic layer, a nonmagnetic layer, and a second ferromagnetic layer; an insulating layer surrounding the laminate; and a sidewall layer provided between the laminate and the insulating layer and surrounding the laminate. At least one of the first ferromagnetic layer and the second ferromagnetic layer contains a Heusler alloy. The sidewall layer is any one of a composite layer in which metal particles containing a metal contained in the Heusler alloy or a metal contained in the nonmagnetic layer are dispersed within metal oxide, a multilayer film including a metal oxide layer containing metal oxide and a metal layer containing the metal contained in the Heusler alloy or the metal contained in the nonmagnetic layer, and a metal layer containing low diffusion coefficient metal selected from a group consisting of Ta, Ru, W, Ir, Pt, Au, and Mo.

### TECHNICAL FIELD

The present disclosure relates to a magnetoresistance effect element.

### BACKGROUND ART

A magnetoresistance effect element is an element in which a resistance value in a laminating direction changes due to the magnetoresistance effect. The magnetoresistance effect element includes two ferromagnetic layers and a nonmagnetic layer sandwiched therebetween. A magnetoresistance effect element in which a conductor is used for the nonmagnetic layer is called a giant magnetoresistance (GMR) element, and a magnetoresistance effect element in which an insulating layer (tunnel barrier layer, barrier layer) is used for the nonmagnetic layer is called a tunnel magnetoresistance (TMR) element. The magnetoresistance effect elements can be used in a variety of applications, such as magnetic sensors, high-frequency components, magnetic heads, and non-volatile random access memories (MRAMs).

Patent Document 1 discloses a magnetoresistance effect element in which a Heusler alloy is used for a ferromagnetic layer. The Heusler alloy has high spin polarization. A magnetic sensor containing a Heusler alloy is expected to have a large output signal.

### CITATION LIST

### Patent Document

Patent Document 1: U.S. Pat. No. 9,336,937B2

### SUMMARY

The spin polarization of the Heusler alloy varies with the composition of the Heusler alloy. If the composition of the Heusler alloy deviates from a predetermined composition, the spin polarization of the Heusler alloy changes, and the MR ratio of the magnetoresistance effect element may decrease.

### Solution to Problem

A magnetoresistance effect element includes: a laminate which includes a first ferromagnetic layer, a nonmagnetic layer, and a second ferromagnetic layer; an insulating layer which surrounds the laminate when viewed from a laminating direction; and a sidewall layer which is provided between the laminate and the insulating layer and surrounds at least a part of the laminate when viewed from the laminating direction. At least one of the first ferromagnetic layer and the second ferromagnetic layer contains a Heusler alloy. The sidewall layer is any one of a composite layer in which metal particles containing a metal contained in the Heusler alloy or a metal contained in the nonmagnetic layer are dispersed within metal oxide, a multilayer film including a metal oxide layer containing metal oxide and a metal layer containing the metal contained in the Heusler alloy or the metal contained in the nonmagnetic layer, and a metal layer containing low diffusion coefficient metal selected from a group consisting of Ta, Ru, W, Ir, Pt, Au, and Mo.

### BRIEF DESCRIPTION OF DRAWINGS

FIG. 1 A cross-sectional view of a magnetoresistance effect element according to a first embodiment.

FIG. 2A A diagram showing the crystal structure of a Heusler alloy.

FIG. 2B A diagram showing the crystal structure of a Heusler alloy.

FIG. 2C A diagram showing the crystal structure of a Heusler alloy.

FIG. 2D A diagram showing the crystal structure of a Heusler alloy.

FIG. 2E A diagram showing the crystal structure of a Heusler alloy.

FIG. 2F A diagram showing the crystal structure of a Heusler alloy.

FIG. 3 A plan view of the magnetoresistance effect element according to the first embodiment.

FIG. 4 An enlarged schematic cross-sectional view of a characteristic part of the magnetoresistance effect element according to the first embodiment.

FIG. 5 An enlarged schematic cross-sectional view of a characteristic part of a magnetoresistance effect element according to a second embodiment.

FIG. 6 An enlarged schematic cross-sectional view of a characteristic part of a magnetoresistance effect element according to a third embodiment.

FIG. 7 A schematic cross-sectional view of a magnetoresistance effect element according to Modified Example 1.

FIG. 8 A cross-sectional view of a magnetic recording element according to Application Example 1.

FIG. 9 A cross-sectional view of a magnetic recording element according to Application Example 2.

FIG. 10 A cross-sectional view of a high-frequency device according to Application Example 3.

### DESCRIPTION OF EMBODIMENTS

Hereinafter, this embodiment will be described in detail by referring to the drawings as appropriate. In the drawings used in the following description, characteristic parts may be enlarged for the sake of convenience in order to make the characteristics of this embodiment easier to understand, and the dimensional ratios of each component may differ from the actual ones. The materials, dimensions, and the like provided as exemplary examples in the following description are merely examples, and the present disclosure is not limited to them and can be implemented with appropriate modifications within the scope that does not change the gist of the disclosure.

### First Embodiment

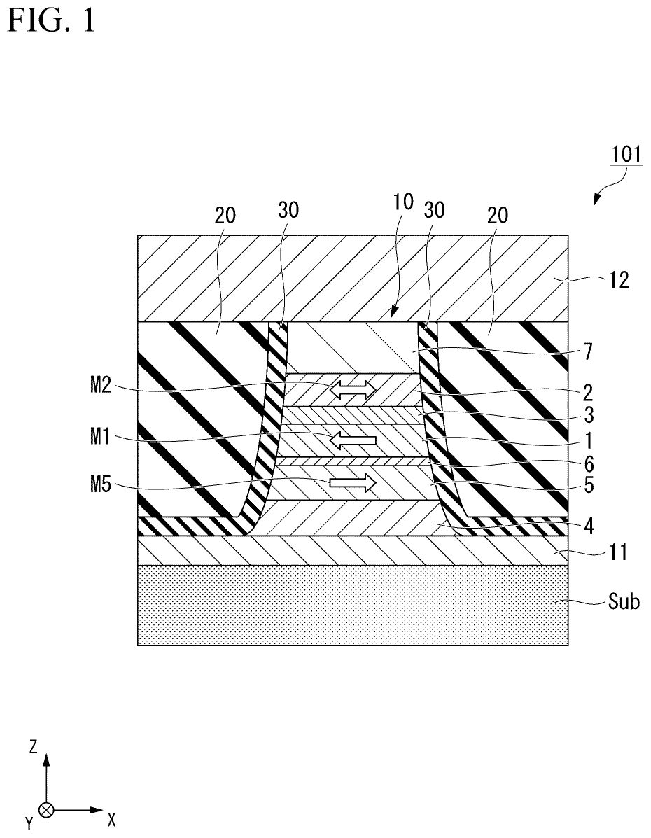

FIG. 1 is a cross-sectional view of a magnetoresistance effect element 101 according to a first embodiment. First, directions will be defined. The laminating direction of each layer is sometimes called the Z direction. Moreover, a direction which intersects with the Z direction and in which each layer extends is called an in-plane direction, one direction thereof is called the X direction, and a direction perpendicular to the X direction and the Z direction is called the Y direction.

The magnetoresistance effect element 101 includes a substrate Sub, a lower electrode 11, a laminate 10, an insulating layer 20, a sidewall layer 30, and an upper electrode 12.

There is no particular limitation on the substrate Sub. The substrate may be crystalline or amorphous. For example, metal oxide single crystals, silicon single crystals, sapphire single crystals, and alumina titanium carbide (AlTiC) are examples of substrates having crystallinity. For example, silicon single crystal with a thermal oxide film, glass, ceramic, and quartz are examples of amorphous substrates.

The lower electrode 11 is on the substrate Sub. The lower electrode 11 also serves as a base layer that serves as a base for the crystal growth of the laminate 10. The lower electrode 11, for example, enhances the crystallinity of the laminate 10. The lower electrode 11 may be a single layer or a multi-layer.

The lower electrode 11 may be crystalline or amorphous. On the amorphous lower electrode 11, the laminate 10 is likely to be oriented with a desired crystallinity. When the lower electrode 11 is crystalline, it is preferable that the lower electrode 11 has a crystal structure close to that of the first ferromagnetic layer 1. The lower electrode 11 includes, for example, one or more selected from a group consisting of Cu, Ag, Cr, W, Mo, Au, Pt, Pd, Rh, Ta, and Ru.

The upper electrode 12 is on the laminate 10. The lower electrode 11 and the upper electrode 12 allow a current to flow in the laminating direction of the laminate 10. There is no particular limitation on the material of the upper electrode 12 as long as it is conductive.

The laminate 10 includes a first ferromagnetic layer 1, a second ferromagnetic layer 2, and a nonmagnetic layer 3. The laminate 10 may include an antiferromagnetic layer 4, a third ferromagnetic layer 5, a magnetic coupling layer 6, and a protective layer 7 in addition to these layers. The laminate 10 outputs a change in the relative angle between the magnetization M1 of the first ferromagnetic layer 1 and the magnetization M2 of the second ferromagnetic layer 2 as a change in resistance value.

The antiferromagnetic layer 4 is, for example, on the lower electrode 11. The antiferromagnetic layer 4 is made of, for example, IrMn, PtMn, or the like. Exchange interaction occurs between the antiferromagnetic layer 4 and the third ferromagnetic layer 5, and the magnetization of the third ferromagnetic layer 5 is strongly fixed.

The third ferromagnetic layer 5 is magnetically coupled to, for example, the first ferromagnetic layer 1. The magnetic coupling is, for example, an antiferromagnetic coupling, which occurs due to the RKKY interaction. The material constituting the third ferromagnetic layer 5 is not particularly limited as long as it is a ferromagnetic material. For example, the third ferromagnetic layer 5 contains Co and Fe. For example, the third ferromagnetic layer 5 is a laminated film in which Co and Pt are alternately laminated, or a laminated film in which Co and Ni are alternately laminated.

The magnetic coupling layer 6 is made of, for example, Ru, Ir, or the like. For example, the magnetic coupling layer 6 has a thickness that allows the third ferromagnetic layer 5 and the first ferromagnetic layer 1 to be antiferromagnetically coupled by the RKKY interaction.

The first ferromagnetic layer 1, the magnetic coupling layer 6, and the third ferromagnetic layer 5 form a synthetic antiferromagnetic structure (SAF structure). The synthetic antiferromagnetic structure is composed of two magnetic layers sandwiching the magnetic coupling layer 6. When the first ferromagnetic layer 1 and the third ferromagnetic layer 5 are antiferromagnetically coupled, the coercive force of the first ferromagnetic layer 1 increases. The first ferromagnetic layer 1, the magnetic coupling layer 6, and the third ferromagnetic layer 5 may be collectively referred to as a magnetization fixed layer.

The first ferromagnetic layer 1 is, for example, on the magnetic coupling layer 6. The first ferromagnetic layer 1 is, for example, closer to the substrate Sub than the second ferromagnetic layer 2.

For example, the magnetization M1 of the first ferromagnetic layer 1 is less likely to move than the magnetization M2 of the second ferromagnetic layer 2. When a predetermined external force is applied, the direction of magnetization M1 of the first ferromagnetic layer 1 does not change (is fixed), and the direction of magnetization M2 of the second ferromagnetic layer 2 changes. The first ferromagnetic layer 1 is also called a pinned layer or a reference layer. The second ferromagnetic layer 2 is also called a free layer.

The second ferromagnetic layer 2 is located opposite to the first ferromagnetic layer 1 with the nonmagnetic layer 3 interposed therebetween. The second ferromagnetic layer 2 is, for example, on the nonmagnetic layer 3. The orientation direction of the magnetization M2 of the second ferromagnetic layer 2 changes regardless of the orientation direction of the magnetization M1 of the first ferromagnetic layer 1. By changing the orientation direction of the magnetization M2 of the second ferromagnetic layer 2, the resistance value in the laminating direction of the laminate 10 changes. The resistance value of the magnetoresistance effect element 101 in the laminating direction is stored as date.

At least one of the first ferromagnetic layer 1 and the second ferromagnetic layer 2 contains a Heusler alloy. Both the first ferromagnetic layer 1 and the second ferromagnetic layer 2 may contain a Heusler alloy.

Heusler alloys are intermetallic compounds with the chemical composition XYZ or X₂YZ. Ferromagnetic Heusler alloys expressed as X₂YZ are called full-Heusler alloys, and ferromagnetic Heusler alloys expressed as XYZ are called half-Heusler alloys. Half-Heusler alloys are full-Heusler alloys in which some of the atoms at the X sites are vacant.

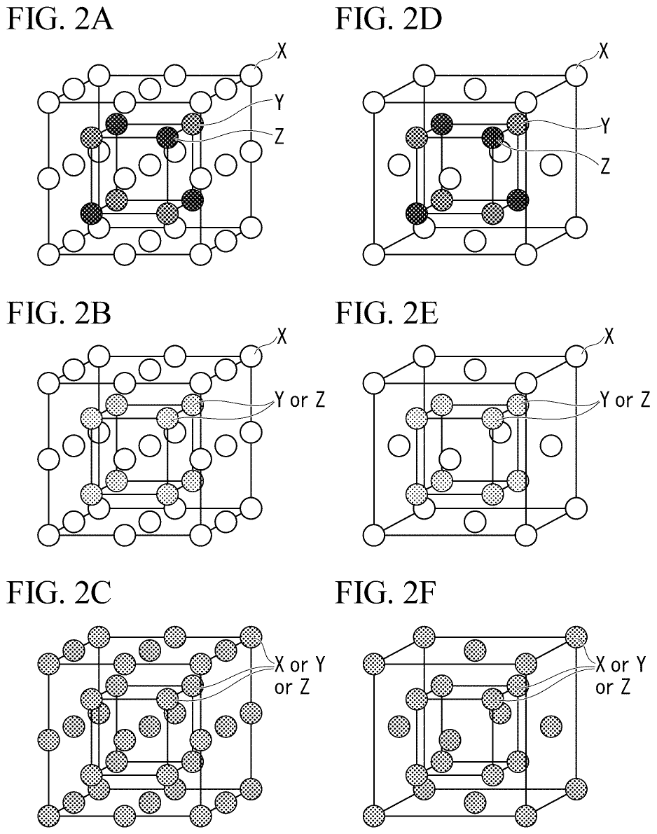

FIGS. 2A to 2F are examples of the crystal structure of the Heusler alloy. FIGS. 2A, 2B, and 2C are examples of the crystal structure of the full-Heusler alloy, and FIGS. 2D, 2E, and 2F are examples of the crystal structure of the half-Heusler alloy.

FIG. 2A is called an L2₁ structure. In the L2₁ structure, the elements in the X site, the Y site, and the Z site are fixed. FIG. 2B is called a B2 structure derived from the L2₁ structure. In the B2 structure, elements in the Y site and elements in the Z site are mixed, and the element in the X site is fixed. FIG. 2C is called an A2 structure derived from the L2₁ structure. In the A2 structure, the elements in the X site, the Y site, and the Z site are mixed.

FIG. 2D is called a C1_{b} structure. In the C1_{b} structure, the elements in the X site, the Y site, and the Z site are fixed. FIG. 2E is called a B2 structure derived from the C1_{b} structure. In the B2 structure, the elements in the Y site and the Z size are mixed, and the element in the X site is fixed. FIG. 2F is called an A2 structure derived from the C1_{b} structure. In the A2 structure, the elements in the X site, the Y site, and the Z site are mixed.

In full-Heusler alloys, the order of crystallinity is L2₁ structure>B2 structure>A2 structure, while in half-Heusler alloys, the order of crystallinity is C1_{b} structure>B2 structure>A2 structure. Although these crystal structures differ in the degree of crystallinity, they are all crystals.

The Heusler alloy is preferably at least partially crystallized. The Heusler alloy may be, for example, entirely crystalline. The Heusler alloy may have, for example, an L2₁ structure or a B2 structure.

Whether or not the Heusler alloy is crystallized can be determined by a transmission electron microscope (TEM) image (for example, a high-angle annular dark-field scanning transmission microscope image: HAADF-STEM image) or an electron beam diffraction image using a transmission electron beam. When the Heusler alloy is crystallized, the atoms are regularly arranged as can be seen in the HAADF-STEM image. More specifically, the Fourier transform image of the HAADF-STEM image shows spots originating from the crystal structure of the Heusler alloy. Furthermore, when the Heusler alloy is crystallized, a diffraction spot from at least one of the (001), (002), (110), (111), and (011) planes can be confirmed in the electron beam diffraction image. When crystallization can be confirmed by at least any one of the means, it can be said that at least a part of the Heusler alloy is crystallized.

In the composition formula of the Heusler alloy (XYZ or X₂YZ), X is a transition metal element of the Co, Fe, Ni, or Cu group on the periodic table or a precious metal, Y is a transition metal element of the Mn, V, Cr, or Ti group or an element type of X, and Z is a typical element of groups III to V. When the Heusler alloy contains Co, X is Co.

The Heusler alloy may be represented, for example, as Co₂Y_{α}Z_{β}. Y is, for example, one or more elements selected from a group consisting of Fe, Mn, and Cr, and Z is, for example, one or more elements selected from a group consisting of Mg, Al, Si, Ti, V, Cr, Ga, and Ge, and satisfies α+β>2. Y is particularly preferably Fe, and Z is particularly preferably Ga and Ge. For example, α satisfies 0.3<α<2.1, and more preferably 0.4<α<2.0. β satisfies 0.1≤β≤2.0.

A full Heusler alloy with a stoichiometric composition is represented as Co₂Y_{α}Z_{β}. When α+β>2 is satisfied, the Co composition ratio is relatively smaller than the sum of the composition ratios of the elements at the Y site and the Z site. When the Co composition ratio is relatively smaller than the sum of the composition ratios of the elements at the Y site and the Z site, it is possible to avoid an antisite in which the elements at the Y site and the Z site are substituted with the element at the X site (Co). Antisites shift the Fermi level of Heusler alloys. The shift in the Fermi level reduces the half-metallicity of the Heusler alloy and reduces its spin polarization. The decrease in spin polarization causes a decrease in the MR ratio of the laminate 10.

The Heusler alloy containing Co may be expressed as, for example, Co₂Fe_{α}Ga_{β1}Ge_{β2}. The composition formula may satisfy α+β1+β2≥2.3, α<β1+β2, 0.5<α<1.9, 0.1≤β1, and 0.1≤β2.

The full Heusler alloy containing Co may be, for example, Co₂FeSi, Co₂FeAl, Co₂FeGeₓGa₁₋ₓ, Co₂MnGeₓGa₁₋ₓ, Co₂MnSi, Co₂MnₓFe₁₋ₓGe. Co₂MnGe, Co₂MnGa, Co₂MnSn, Co₂MnAl, Co₂CrAl, Co₂VAl, Co₂Mn₁₋ₐFeₐAl_{b}Si_{1-b}, or the like. The half-Heusler alloy containing Co may be, for example, CoFeSb or CoMnSb.

The nonmagnetic layer 3 is between the first ferromagnetic layer 1 and the second ferromagnetic layer 2 in the Z direction. The nonmagnetic layer 3 has a thickness in the range of, for example, 1 nm to 10 nm. The nonmagnetic layer 3 inhibits magnetic coupling between the first ferromagnetic layer 1 and the second ferromagnetic layer 2.

The nonmagnetic layer 3 contains, for example, a nonmagnetic metal. The nonmagnetic layer 3 may be made of, for example, nonmagnetic metal, an alloy of nonmagnetic metal, or a composite of metal and oxide. The nonmagnetic layer 3 contains, for example, any element selected from a group consisting of Cu, Au, Ag, Al, Cr, and Ni. The nonmagnetic layer 3 may be, for example, Ag, AgSn, CuZn, AgIn/ZnO—MnO, or Al/MgO. Metals or alloys containing these elements have excellent electrical conductivity and reduce the RA of the magnetoresistance effect element 101.

The protective layer 7 is on the laminate 10. The protective layer 7 protects the second ferromagnetic layer 2. The protective layer 7 is also called a cap layer. The protective layer 7 suppresses the diffusion of atoms from the second ferromagnetic layer 2. The protective layer 7 also contributes to the crystal orientation of each layer of the laminate 10. The magnetization of the first ferromagnetic layer 1 and the second ferromagnetic layer 2 is stabilized by the presence of the protective layer 7, and the MR ratio of the magnetoresistance effect element 101 is improved. The protective layer 7 may be a single layer or multiple layers. The protective layer 7 may contain, for example, Ru, Ir, Ta, Ti, Al, Au, Ag, Pt, or Cu.

The composition of each layer can be determined using energy dispersive X-ray analysis (EDS). By carrying out EDS line analysis, for example, the composition distribution of each material in the film thickness direction can be confirmed.

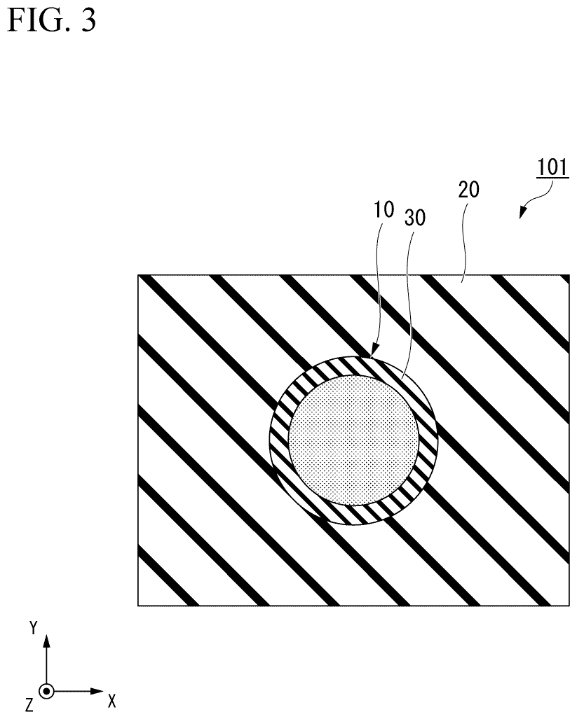

FIG. 3 is a plan view of the magnetoresistance effect element 101 according to the first embodiment when viewed from the Z direction. FIG. 3 is a plan view of a cross section of the magnetoresistance effect element 101 cut along the XY plane passing through the second ferromagnetic layer 2 of the laminate 10. The insulating layer 20 surrounds the laminate 10 when viewed from the Z direction.

The insulating layer 20 is made of, for example, an oxide, a nitride, or an oxynitride of Si, Al, and Mg. The insulating layer 20 is made of, for example, silicon oxide (SiOx), silicon nitride (SiNx), silicon carbide (SiC), chromium nitride (CrN), silicon carbonitride (SiCN), silicon oxynitride (SiON), aluminum oxide (Al₂O₃), zirconium oxide (ZrOx), or the like.

The sidewall layer 30 is between the laminate 10 and the insulating layer 20. The sidewall layer 30 prevents elements from diffusing from the laminate 10 toward the insulating layer 20. The sidewall layer 30 surrounds at least a part of the laminate 10 when viewed from the Z direction.

For example, the sidewall layer 30 surrounds at least the second ferromagnetic layer 2 in the laminate 10. If the elements constituting the second ferromagnetic layer 2 diffuse into the insulating layer 20, the composition of the second ferromagnetic layer 2 deviates from the desired composition. In particular, if the composition of the second ferromagnetic layer 2 is deviated, the MR ratio of the magnetoresistance effect element 101 decreases. The sidewall layer 30 may cover the entire periphery of the laminate 10.

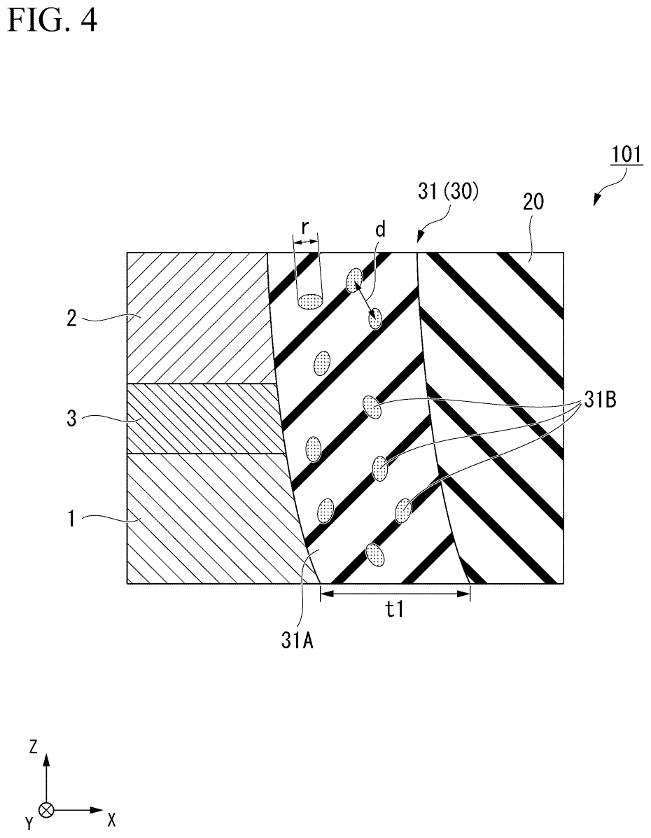

FIG. 4 is an enlarged schematic cross-sectional view of the vicinity of the sidewall layer 30 of the magnetoresistance effect element 101 according to the first embodiment. The sidewall layer 30 of the first embodiment is a composite layer 31.

The composite layer 31 includes metal oxide 31A and metal particles 31B. The metal particles 31B are dispersed within the metal oxide 31A. The thickness t1 of the composite layer 31 is, for example, 2 nm or more and 20 nm or less. The thickness t1 of the composite layer 31 is, for example, the thickness at the same height as the first ferromagnetic layer 1. The composite layer 31 prevents element diffusion from the laminate 10 to the insulating layer 20. If the thickness of the composite layer 31 is within the above range, element diffusion can be sufficiently prevented.

The metal oxide 31A traps oxygen. The metal oxide 31A prevents the occurrence of a shunt current through the composite layer 31 in the laminate 10. The metal oxide 31A is, for example, at least one selected from a group consisting of magnesium oxide, aluminum oxide, chromium oxide, zirconium oxide, copper oxide, manganese oxide, and titanium oxide. The metal oxide is not limited to a stoichiometric composition, and may contain excess oxygen or may have an oxygen deficiency.

The metal particles 31B contain metal contained in a Heusler alloy or metal contained in the nonmagnetic layer 3. The metal contained in the Heusler alloy is, for example, any one selected from a group consisting of Ga, Ge, Fe, Co, Si, Mn, Al, Mg, Ti, and Cr. The metal contained in the nonmagnetic layer 3 is, for example, Ag or Sn. The metal particles 31B reduce the difference in element concentration between the laminate 10 and the insulating layer 20 and prevent element diffusion. Furthermore, the metal particles 31B trap oxygen.

The particle diameter r of the metal particles 31B is, for example, 0.5 nm or more and 10 nm or less. The particle diameter r is an average value of the diameters of 100 or more metal particles 31B. When the metal particle 31B has an irregular shape, the length in the major axis direction is treated as the diameter. The diameter of each metal particle 31B can be measured using, for example, a transmission electron microscope (TEM).

The interparticle distance d of the metal particles 31B is, for example, 0.5 nm or more and 10 nm or less. The interparticle distance d is an average value of the nearest interparticle distances d of 100 or more pairs of metal particles 31B. The interparticle distance d can be measured, for example, using a transmission electron microscope (TEM).

When the particle diameter r and the interparticle distance d of the metal particles 31B are within the above ranges, the metal particles 31B can be uniformly dispersed within the metal oxide 31A.

Next, a method of manufacturing the magnetoresistance effect element 101 will be described. The magnetoresistance effect element 101 can be manufactured by depositing each layer in order. Each layer can be deposited by, for example, a sputtering method.

The composite layer 31 can be produced by forming the laminate 10 and then performing sputtering so as to cover the periphery of the laminate 10. For example, the composite layer 31 can be obtained by simultaneously sputtering the elements constituting the metal particles 31B and the elements constituting the metal oxide 31A. The particle diameter r and the interparticle distance d of the metal particles 31B can be changed by changing the gas pressure, gas flow rate, gas gradient, temperature, voltage applied to the target, and the like during sputtering.

After the composite layer 31 is formed, the insulating layer 20 is formed and polished until the protective layer 7 of the laminate 10 is exposed. Then, the upper electrode 12 is formed on one surface of the laminate 10, thereby obtaining the magnetoresistance effect element 101.

In the magnetoresistance effect element 101 according to this embodiment, since the composite layer 31 prevents element diffusion from the laminate 10, it is possible to suppress deviation of the composition of the Heusler alloy constituting the first ferromagnetic layer 1 or the second ferromagnetic layer 2 from the desired composition. Therefore, the magnetoresistance effect element 101 according to this embodiment has a large MR ratio.

### Second Embodiment

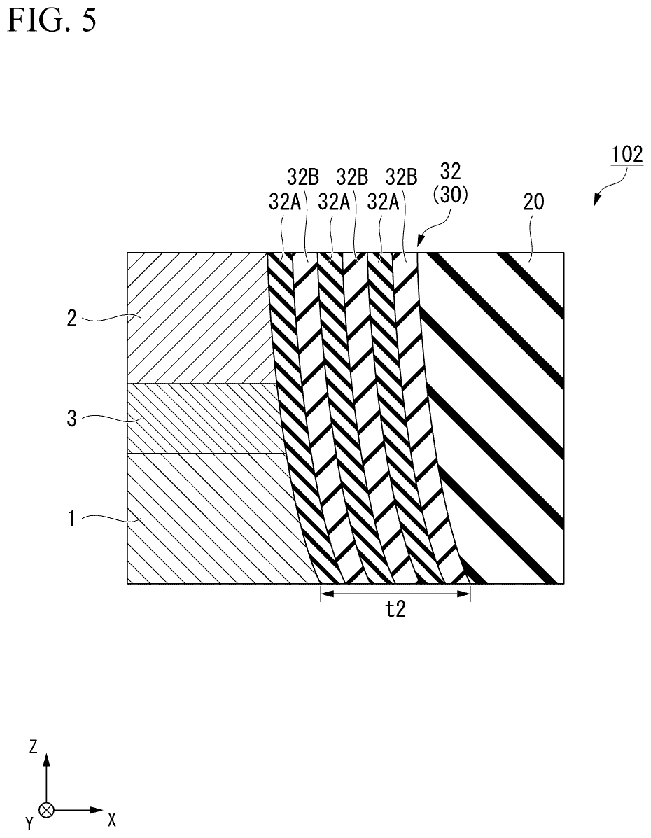

FIG. 5 is a cross-sectional view of a magnetoresistance effect element 102 according to a second embodiment. The magnetoresistance effect element 102 differs from the magnetoresistance effect element 101 in that the sidewall layer 30 is a multilayer film 32. This magnetoresistance effect element is the same as the magnetoresistance effect element 101 except for the configuration of the sidewall layer 30 of the magnetoresistance effect element 102.

The multilayer film 32 surrounds the laminate 10 when viewed from the Z direction. The thickness t2 of the multilayer film 32 is, for example, 2.0 nm or more and 10.0 nm or less. The thickness t2 of the multilayer film 32 is, for example, the thickness at the same height as the first ferromagnetic layer 1. The multilayer film 32 prevents element diffusion from the laminate 10 to the insulating layer 20. If the thickness of the multilayer film 32 is within the above range, element diffusion can be sufficiently prevented.

The multilayer film 32 includes a metal oxide layer 32A containing metal oxide and a metal layer 32B containing metal contained in a Heusler alloy or metal contained in a nonmagnetic layer. The metal oxide layer 32A and the metal layer 32B are alternately deposited.

The metal oxide layer 32A contains metal oxide. The metal oxide is the same as the metal oxide 31A of the first embodiment. The metal oxide layer 32A prevents the occurrence of a shunt current through the multilayer film 32 in the laminate 10. In the multilayer film 32, the layer closest to the laminate 10 is preferably the metal oxide layer 32A.

The metal layer 32B contains metal contained in a Heusler alloy or metal contained in the nonmagnetic layer 3. The metal contained in the Heusler alloy and the metal contained in the nonmagnetic layer 3 are the same as those of the first embodiment. The metal layer 32B reduces the difference in element concentration between the laminate 10 and the insulating layer 20 and prevents element diffusion. Furthermore, the metal layer 32B traps oxygen.

The multilayer film 32 can be formed by forming the laminate 10 and then alternately sputtering the elements constituting the metal oxide layer 32A and the elements constituting the metal layer 32B.

In the magnetoresistance effect element 102 according to this embodiment, since the multilayer film 32 prevents element diffusion from the laminate 10, it is possible to suppress deviation of the composition of the Heusler alloy constituting the first ferromagnetic layer 1 or the second ferromagnetic layer 2 from the desired composition. Therefore, the magnetoresistance effect element 102 according to this embodiment has a large MR ratio.

### Third Embodiment

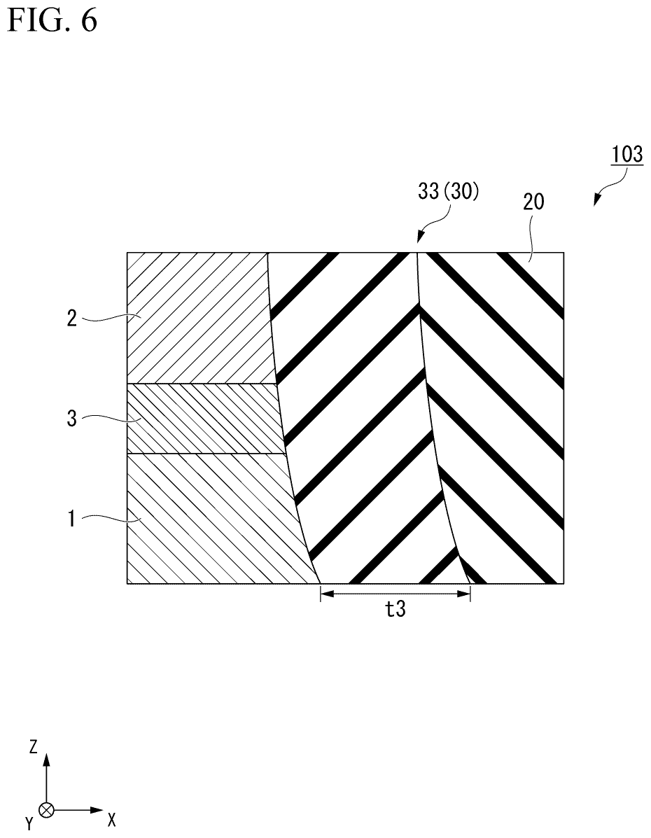

FIG. 6 is a cross-sectional view of a magnetoresistance effect element 103 according to a third embodiment. The magnetoresistance effect element 103 differs from the magnetoresistance effect element 101 in that the sidewall layer 30 is a metal layer 33. This magnetoresistance effect element is the same as the magnetoresistance effect element 101 except for the configuration of the sidewall layer 30 of the magnetoresistance effect element 103.

The metal layer 33 surrounds the laminate 10 when viewed from the Z direction. The thickness t3 of the metal layer 33 is, for example, 1 nm or more and 5 nm or less. The thickness t3 of the metal layer 33 may be, for example, 2 nm or more and 5 nm or less. The thickness t3 of the metal layer 33 is, for example, the thickness at the same height as the first ferromagnetic layer 1. The metal layer 33 prevents element diffusion from the laminate 10 to the insulating layer 20. If the thickness of the metal layer 33 is within the above range, element diffusion can be sufficiently prevented.

The metal layer 33 contains metal with a low diffusion coefficient. The diffusion coefficient of the metal layer 33 is, for example, 10 m²/s or more and 18 m²/s or less at a temperature of 300° C. The metal layer 33 includes at least one selected from a group consisting of Ta, Ru, W, Ir, Pt, Au, and Mo. These elements may exist either alone or as alloys. Since the metal layer 33 contains metal with a low diffusion coefficient, it is possible to inhibit the diffusion of elements from the laminate 10 into the insulating layer 20.

Since the metal layer 33 is conductive, a shunt current may occur through the metal layer 33 in the laminate 10. However, the metal layer 33 is thin enough that shunt current through metal layer 33 does not have a significant effect.

The metal layer 33 can be formed by sputtering the elements that constitute the metal layer 33 after the laminate 10 is formed.

In the magnetoresistance effect element 103 according to this embodiment, since the metal layer 33 prevents element diffusion from the laminate 10, it is possible to suppress deviation of the composition of the Heusler alloy constituting the first ferromagnetic layer 1 or the second ferromagnetic layer 2 from the desired composition. Therefore, the magnetoresistance effect element 103 according to this embodiment has a large MR ratio.

Although several embodiments have been described in detail above with reference to the drawings, each configuration and their combinations are merely examples, and addition, omission, substitution, and other modifications of the configurations are possible without departing from the spirit of this disclosure.

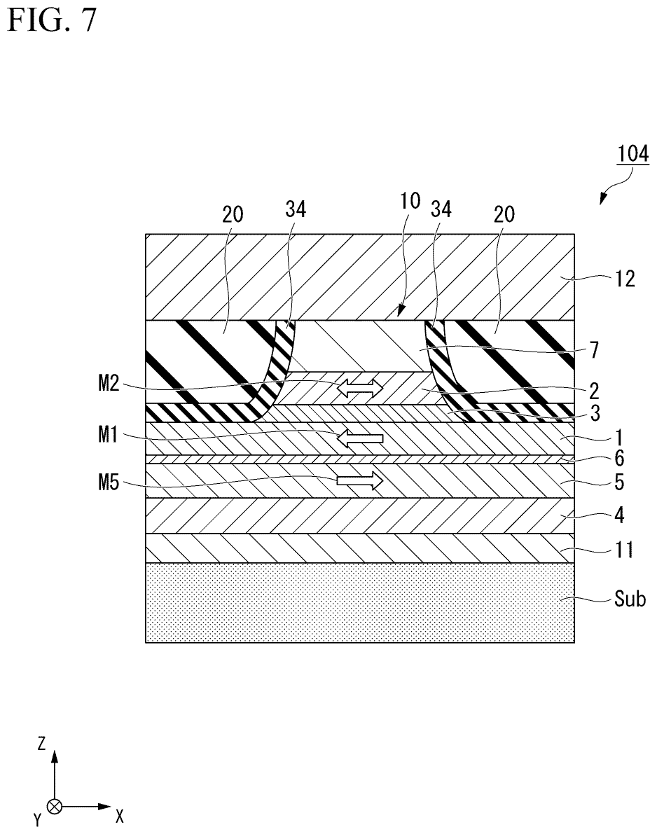

For example, FIG. 7 is a schematic cross-sectional view of a magnetoresistance effect element 104 according to Modified Example 1. The magnetoresistance effect element 104 according to Modified Example 1 differs from the sidewall layer 30 of the magnetoresistance effect element 101 in that the sidewall layer 34 does not cover the entire surface of the laminate 10. The sidewall layer 34 surrounds, for example, a part of the nonmagnetic layer 3, the second ferromagnetic layer 2, and the protective layer 7. In the magnetoresistance effect element 104 according to Modified Example 1, since the volumes of the first ferromagnetic layer 1 and the third ferromagnetic layer 5 are large, the magnetization M1 of the first ferromagnetic layer 1 is excellent in stability. The sidewall layer 34 may have the same configuration as the composite layer 31 shown in the first embodiment, the multilayer film 32 shown in the second embodiment, or the metal layer 33 shown in the third embodiment.

The above-described magnetoresistance effect elements 101, 102, 103, and 104 can be used for various purposes. The magnetoresistance effect elements 101, 102, 103, and 104 can be applied to, for example, magnetic heads, magnetic sensors, magnetic memories, and high-frequency filters.

Next, application examples of the magnetoresistance effect element according to this embodiment will be described. Furthermore, in the following application examples, the magnetoresistance effect element 101 is used, but the magnetoresistance effect element is not limited thereto.

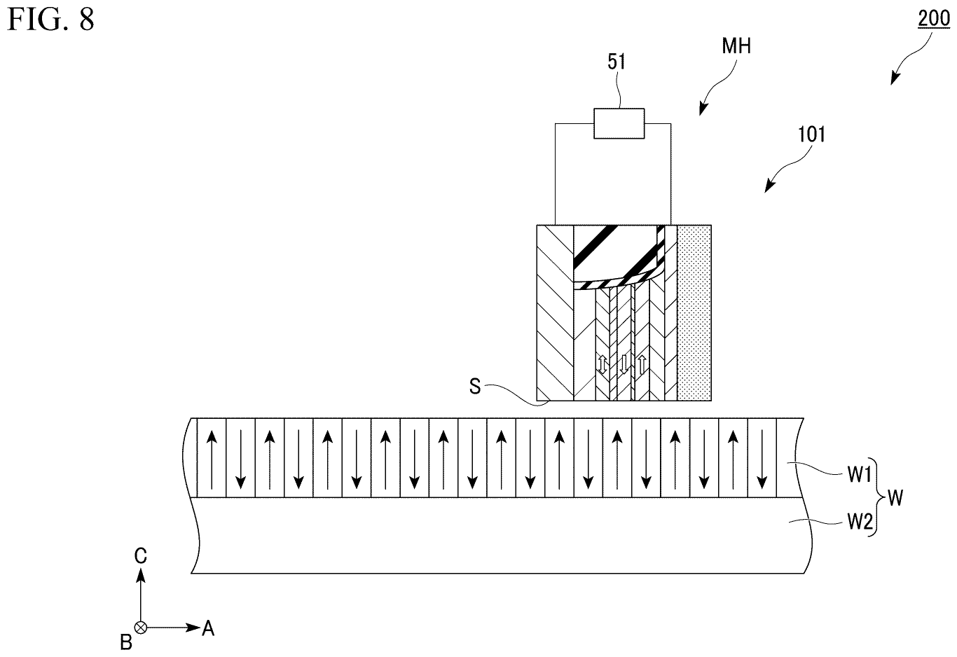

FIG. 8 is a cross-sectional view of the magnetic recording element 200 according to Application Example 1. FIG. 8 is a cross-sectional view of the magnetoresistance effect element 101 cut along the laminating direction.

As shown in FIG. 8, the magnetic recording element 200 includes a magnetic head MH and a magnetic recording medium W. In FIG. 8, one direction in which the magnetic recording medium W extends is defined as the A direction, and a direction perpendicular to direction A is defined as the B direction. The AB plane is parallel to the main surface of the magnetic recording medium W. The direction connecting the magnetic recording medium W and the magnetic head MH and perpendicular to the AB plane is defined as the C direction.

The magnetic head MH has an air bearing surface (medium facing surface) S facing the surface of the magnetic recording medium W. The magnetic head MH moves in the directions of arrows +A and −A along the surface of the magnetic recording medium W at a position spaced a certain distance from the magnetic recording medium W. The magnetic head MH includes a magnetoresistive element 101 that acts as a magnetic sensor and a magnetic recording unit (not shown). A resistance measuring device 51 measures the resistance value of the magnetoresistance effect element 101 in the laminating direction.

The magnetic recording unit applies a magnetic field to a recording layer W1 of the magnetic recording medium W, and determines the magnetization direction of the recording layer W1. That is, the magnetic recording unit performs magnetic recording on the magnetic recording medium W. The magnetoresistance effect element 101 reads the magnetization information of the recording layer W1 written by the magnetic recording unit.

The magnetic recording medium W includes the recording layer W1 and an underlayer W2. The recording layer W1 is a portion where magnetic recording is performed, and the underlayer W2 is a magnetic path (path of magnetic flux) that returns the magnetic flux for writing to the magnetic head MH. The recording layer W1 records magnetic information as the magnetization direction.

The first ferromagnetic layer 1 of the magnetoresistance effect element 101 has a fixed magnetization direction. The second ferromagnetic layer 2 exposed to the air bearing surface S is influenced by the magnetization recorded in the recording layer W1 of the opposing magnetic recording medium W. For example, in FIG. 8, the magnetization direction of the second ferromagnetic layer 2 is oriented in the +C direction due to the influence of magnetization oriented in the +C direction of the recording layer W1.

Here, the resistance when the magnetization directions of the first ferromagnetic layer 1 and the second ferromagnetic layer 2 are parallel is different from the resistance when the magnetization directions of the first ferromagnetic layer 1 and the second ferromagnetic layer 2 are antiparallel. The MR ratio of the magnetoresistance effect element 101 increases as the difference between the resistance value in the parallel case and the resistance value in the antiparallel case increases. The magnetoresistance effect element 101 according to this embodiment has a large MR ratio. Therefore, the resistance measuring device 51 can accurately read out information about the magnetization of the recording layer W1 as a change in resistance value.

There is no particular limitation on the shape of the magnetoresistance effect element 101 of the magnetic head MH. For example, in order to avoid the influence of the leakage magnetic field of the magnetic recording medium W on the first ferromagnetic layer 1 of the magnetoresistance effect element 101, the first ferromagnetic layer 1 may be disposed at a position away from the magnetic recording medium W.

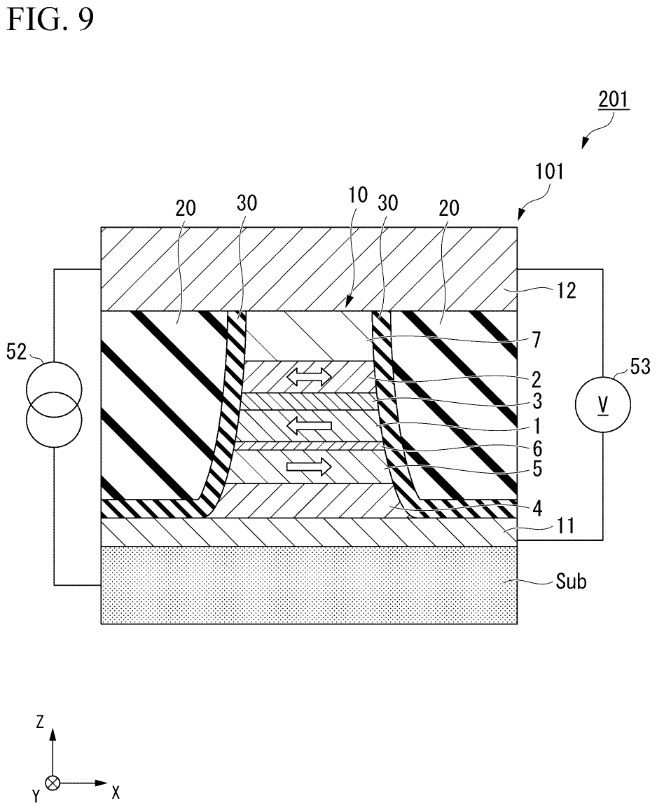

FIG. 9 is a cross-sectional view of a magnetic recording element 201 according to Application Example 2. FIG. 9 is a cross-sectional view of the magnetic recording element 201 cut along the laminating direction.

As shown in FIG. 9, the magnetic recording element 201 includes the magnetoresistance effect element 101, a power supply 52, and a measuring unit 53. The power supply 52 applies a potential difference in the laminating direction of the magnetoresistance effect element 101. The power supply 52 is, for example, a DC power supply. The measuring unit 53 measures the resistance value in the laminating direction of the magnetoresistance effect element 101.

When a potential difference is generated between the first ferromagnetic layer 1 and the second ferromagnetic layer 2 by the power supply 52, a current flows in the laminating direction of the magnetoresistance effect element 101. The current is spin-polarized when passing through the first ferromagnetic layer 1, and becomes a spin polarized current. t. The spin-polarized current flows through the nonmagnetic layer 3 to the second ferromagnetic layer 2. The magnetization of the second ferromagnetic layer 2 is reversed by receiving a spin transfer torque (STT) due to a spin-polarized current. By changing the relative angle between the magnetization direction of the first ferromagnetic layer 1 and the magnetization direction of the second ferromagnetic layer 2, the resistance value in the laminating direction of the magnetoresistance effect element 101 changes. The resistance value in the laminating direction of the magnetoresistance effect element 101 is read by the measuring unit 53. That is, the magnetic recording element 201 shown in FIG. 9 is a spin transfer torque (STT) type magnetic recording element.

The magnetic recording element 201 shown in FIG. 9 has a large MR ratio. If the MR ratio of the magnetoresistance effect element 101 is large, the magnetic recording element 201 can accurately record data.

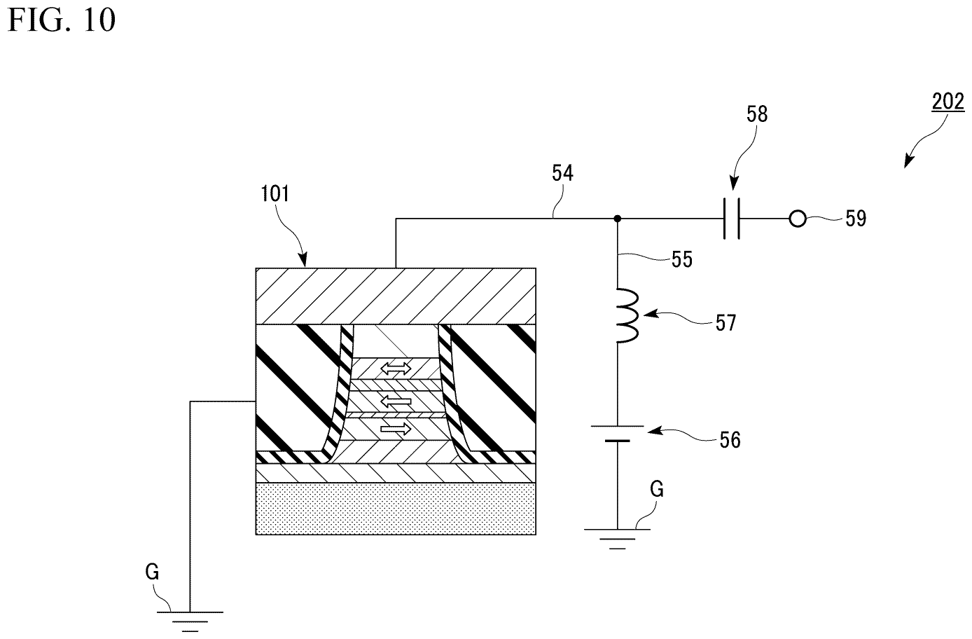

FIG. 10 is a schematic view of a high-frequency device 202 according to Application Example 3. As shown in FIG. 10, the high-frequency device 202 includes the magnetoresistance effect element 101, a DC power supply 56, an inductor 57, a capacitor 58, an output port 59, and wirings 54 and 55.

The wiring 54 connects the magnetoresistance effect element 101 and the output port 59. The wiring 55 branches off from the wiring 54 and reaches a ground G via the inductor 57 and the DC power supply 56. The DC power supply 56, the inductor 57, and the capacitor 58 may be of known types. The inductor 57 cuts the high-frequency components of the current and passes the constant components of the current. The capacitor 58 passes the high-frequency components of the current and cuts the constant components of the current. The inductor 57 is disposed in a portion where it is desired to suppress the flow of high-frequency current, and the capacitor 58 is disposed in a portion where it is desired to suppress the flow of direct current.

When an AC current or an AC magnetic field is applied to the ferromagnetic layer included in the magnetoresistance effect element 101, the magnetization of the second ferromagnetic layer 2 precesses. The magnetization of the second ferromagnetic layer 2 oscillates strongly when the frequency of the high-frequency current or high-frequency magnetic field applied to the second ferromagnetic layer 2 is close to the ferromagnetic resonance frequency of the second ferromagnetic layer 2, and does not oscillate much at frequencies far from the ferromagnetic resonance frequency of the second ferromagnetic layer 2. This phenomenon is called ferromagnetic resonance.

The resistance value of the magnetoresistance effect element 101 changes due to the oscillation of the magnetization of the second ferromagnetic layer 2. The DC power supply 56 applies a DC current to the magnetoresistance effect element 101. A direct current flows in the laminating direction of the magnetoresistance effect element 101. The direct current flows through the wirings 54 and 55 and the magnetoresistance effect element 101 to the ground G. The potential of the magnetoresistance effect element 101 changes according to Ohm's law. A high-frequency signal is output from the output port 59 in response to a change in potential (change in resistance value) of the magnetoresistance effect element 101.

Since the high-frequency device 202 shown in FIG. 10 includes the magnetoresistance effect element 101 with a large change range in resistance value, it is possible to transmit a high-frequency signal with a large output.

### EXAMPLES

### Example 1

As Example 1, the laminate 10 was first produced on the substrate Sub. The composition of each layer was as follows.
Substrate Sub: Silicon with thermal oxide film
Lower electrode 11: Ag, film thickness 100.0 nm
Antiferromagnetic layer 4: IrMn, film thickness 8.0 nm
Third ferromagnetic layer 5: CoFe, film thickness 4.0 nm
Magnetic coupling layer 6: Ru, film thickness 0.8 nm
First ferromagnetic layer 1: Co₂Fe_{0.9}Ga_{0.5}Ge_{0.9}, film thickness 4.0 nm
Nonmagnetic layer 3: AgSn, film thickness 5.0 nm
Second ferromagnetic layer 2: Co₂Fe_{0.9}Ga_{0.5}Ge_{0.9}, film thickness 4.0 nm
Protective layer 7: Ru, film thickness 4.0 nm

Next, the composite layer 31 was formed to cover the laminate 10. The composite layer 31 was produced by simultaneously sputtering of these elements, using Al₂O₃ as the metal oxide and Ge as the metal particles.

Next, the insulating layer 20 was formed to cover the composite layer 31. A part of the composite layer 31 and the insulating layer 20 were polished until the surface of the protective layer 7 was exposed to form the upper electrode 12. The insulating layer 20 was SiO₂, and the upper electrode 12 was Ta/Au.

The laminate was annealed. Annealing was performed in a magnetic field and is also called heat treatment in a magnetic field. In order to impart magnetic anisotropy such as uniaxial magnetic anisotropy, annealing was performed at 320° C. for 12 hours while applying a magnetic field. By this order, the magnetoresistance effect element 101 was produced.

A cross section of the magnetoresistance effect element 101 was photographed with a transmission electron microscope (TEM) and it was confirmed that metal particles 31B were dispersed within the metal oxide 31A within the composite layer 31.

The MR ratio of the magnetoresistance effect element 101 of Example 1 was measured. As the MR ratio, a change in resistance value of the magnetoresistance effect element 101 was measured by monitoring the voltage applied to the magnetoresistance effect element 101 with a voltmeter while sweeping a magnetic field from outside the magnetoresistance effect element 101 when a constant current flows in the laminating direction of the magnetoresistance effect element. The MR ratio was calculated from the following formula using the resistance value measured when the magnetization M1 of the first ferromagnetic layer 1 and the magnetization M2 of the second ferromagnetic layer 2 were parallel to each other and the resistance value measured when the magnetization M1 of the first ferromagnetic layer 1 and the magnetization M2 of the second ferromagnetic layer 2 were antiparallel to each other. The MR ratio was measured at 300 K (room temperature).

MR ratio (%)=(R_{AP}−R_{P})/R_{P}×100

R_{P} is the resistance value when the magnetization M1 of the first ferromagnetic layer 1 and the magnetization M2 of the second ferromagnetic layer 2 are oriented parallel to each other, and R_{AP} is the resistance value when the magnetization M1 of the first ferromagnetic layer 1 and the magnetization M2 of the second ferromagnetic layer 2 are oriented anti-parallel to each other.

The MR ratio of the magnetoresistance effect element 101 according to Example 1 was 13.2%.

### Example 2

Example 2 differs from Example 1 in that the multilayer film 32 was formed instead of the composite layer 31. The multilayer film 32 was produced by alternately sputtering Al₂O₃ as the metal oxide layer 32A and Ge as the metal layer 32B.

The MR ratio of the magnetoresistance effect element 102 according to Example 2 was 13.2%.

### Example 3

Example 3 differs from Example 1 in that the metal layer 33 was formed instead of the composite layer 31. The metal layer 33 was prepared by sputtering Ta.

The MR ratio of the magnetoresistance effect element 103 of Example 3 was 12.5%.

### Examples 4 to 6

Examples 4 to 6 differ from Example 1 in that the metal species constituting the metal particles 31B was changed. The configurations of the metal particles 31B of Examples 4 to 6 and the MR ratios of each are shown below.
Example 4: Fe, 13.1%
Example 5: Ag, 13.5%
Example 6: Sn, 13.0%

### Examples 7 to 9

Examples 7 to 9 differ from Example 1 in that the material species constituting the metal oxide 31A was changed. The metal oxides 31A of Examples 7 to 9 and their respective MR ratios are shown below.
Example 7: MgO, 13.6%
Example 8: CrO, 13.2%
Example 9: TiO, 12.8%

### Examples 10 to 12

Examples 10 to 12 differ from Example 2 in that the metal species constituting the metal layer 32B was changed. The configurations of the metal layers 32B of Examples 10 to 12 and their respective MR ratios are shown below.
Example 10: Fe, 12.8%
Example 11: Ag, 12.5%
Example 12: Sn, 12.9%

### Examples 13 to 15

Examples 13 to 15 differ from Example 2 in that the material species constituting the metal oxide layer 32A was changed. The metal oxide layers 32A of Examples 13 to 15 and their respective MR ratios are shown below.
Example 13: MgO, 13.3%
Example 14: CrO, 13.1%
Example 15: TiO, 12.8%

### Examples 16 to 21

Examples 16 to 21 differ from Example 3 in that the metal species constituting the metal layer 33 was changed. The configurations of the metal layer 33 in Examples 16 to 21 and their respective MR ratios are shown below.
Example 16: W, 12.2%
Example 17: Pt, 12.6%
Example 18: Mo, 12.9%
Example 19: Ru, 12.4%
Example 20: Ir, 12.8%
Example 21: Au, 12.1%

### Comparative Example 1

Comparative Example 1 differs from Example 1 in that no layer corresponding to the sidewall layer 30 (composite layer 31) was formed. The MR ratio of the magnetoresistance effect element of Comparative Example 1 was 8.5%.

The magnetoresistance effect elements of Examples 1 to 21 had a larger MR ratio than the magnetoresistance effect element of Comparative Example 1. This is believed to be because the sidewall layer 30 suppresses the diffusion of elements from the laminate 10.

### REFERENCE SIGNS LIST

1 First ferromagnetic layer
2 Second ferromagnetic layer
3 Nonmagnetic layer
4 Antiferromagnetic layer
5 Third ferromagnetic layer
6 Magnetic coupling layer
7 Protective layer
10 Laminate
11 Lower electrode
12 Upper electrode
20 Insulating layer
30 Sidewall layer
31 Composite layer
31A Metal oxide
31B Metal particles
32 Multilayer film
32A Metal oxide layer
32B, 33 Metal layer
34 Sidewall layer
51 Resistance measuring device
52 Power supply
53 Measuring unit
54, 55 Wiring
56 DC power supply
57 Inductor
58 Capacitor
59 Output port
101, 102, 103, 104 Magnetoresistance effect element
200 Magnetic recording element
201 Magnetic recording element
202 High-frequency device

What is claimed is:

1. A magnetoresistance effect element comprising:
a laminate which includes a first ferromagnetic layer, a nonmagnetic layer, and a second ferromagnetic layer;
an insulating layer which surrounds the laminate when viewed from a laminating direction; and
a sidewall layer which is provided between the laminate and the insulating layer and surrounds at least a part of the laminate when viewed from the laminating direction,
wherein at least one of the first ferromagnetic layer and the second ferromagnetic layer contains a Heusler alloy, and
wherein the sidewall layer is any one of a composite layer in which metal particles containing a metal contained in the Heusler alloy or a metal contained in the nonmagnetic layer are dispersed within metal oxide, a multilayer film including a metal oxide layer containing metal oxide and a metal layer containing the metal contained in the Heusler alloy or the metal contained in the nonmagnetic layer, and a metal layer containing low diffusion coefficient metal selected from a group consisting of Ta, Ru, W, Ir, Pt, Au, and Mo.

2. The magnetoresistance effect element according to claim 1,
wherein the metal contained in the Heusler alloy is any one selected from a group consisting of Ga, Ge, Fe, Co, Si, Mn, Al, Mg, Ti, and Cr.

3. The magnetoresistance effect element according to claim 1,
wherein the metal oxide is at least one selected from a group consisting of magnesium oxide, aluminum oxide, chromium oxide, zirconium oxide, copper oxide, manganese oxide, and titanium oxide.

4. The magnetoresistance effect element according to claim 1,
wherein the sidewall layer is the composite layer in which metal particles containing the metal contained in the Heusler alloy or the metal contained in the nonmagnetic layer are dispersed within metal oxide.

5. The magnetoresistance effect element according to claim 4,
wherein the composite layer has a thickness of 2 nm or more and 20 nm or less.

6. The magnetoresistance effect element according to claim 4,
wherein the metal particles have an average particle diameter of 0.5 nm or more and 10 nm or less.

7. The magnetoresistance effect element according to claim 4,
wherein an average interparticle distance of the metal particles is 0.5 nm or more and 10 nm or less.

8. The magnetoresistance effect element according to claim 1,
wherein the sidewall layer is the multilayer film including the metal oxide layer containing metal oxide and the metal layer containing the metal contained in the Heusler alloy or the metal contained in the nonmagnetic layer.

9. The magnetoresistance effect element according to claim 8,
wherein the multilayer film has a thickness of 2.0 nm or more and 10.0 nm or less.

10. The magnetoresistance effect element according to claim 1,
wherein the sidewall layer is the metal layer containing low diffusion coefficient metal selected from a group consisting of Ta, Ru, W, Ir, Pt, Au, and Mo.

11. The magnetoresistance effect element according to claim 10,
wherein the metal layer has a thickness of 2.0 nm or more and 5.0 nm or less.

12. The magnetoresistance effect element according to claim 1,
wherein the sidewall layer covers the entire side surface of the laminate.

13. The magnetoresistance effect element according to claim 1,
wherein the Heusler alloy is represented as Co₂Y_{α}Z_{β},
wherein Y is one or more elements selected from a group consisting of Fe, Mn, and Cr,
wherein Z is one or more elements selected from a group consisting of Mg, Al, Si, Ti, V, Cr, Ga, and Ge, and
wherein α+β>2 is satisfied.

14. The magnetoresistance effect element according to claim 1,
wherein the nonmagnetic layer is a metal alloy or a composite of metal and oxide.

15. The magnetoresistance effect element according to claim 1,
wherein the first ferromagnetic layer and the second ferromagnetic layer each contains a Heusler alloy.

16. A magnetic sensor comprising:
the magnetoresistance effect element according to claim 1.

17. A magnetic memory comprising:
the magnetoresistance effect element according to claim 1.
